(19) United States
(12) Patent Application Publication
(10) Pub. No.: US 2011/0063486 A1
(43) Pub. Date: Mar. 17, 2011

(54) SOLID-STATE IMAGING DEVICE AND METHOD OF MANUFACTURING THE SAME

(75) Inventors: Kosaku SAEKI, Niigata (JP); Motonari KATSUNO, Kyoto (JP); Kazuhiro YAMASHITA, Hyogo (JP)

(73) Assignee: PANASONIC CORPORATION, Osaka (JP)

(21) Appl. No.: 12/950,387

(22) Filed: Nov. 19, 2010

Related U.S. Application Data
(63) Continuation of application No. PCT/JP2009/001328, filed on Mar. 25, 2009.

(30) Foreign Application Priority Data
May 28, 2008 (JP) 2008-140112

(51) Int. Cl. H04N 5/335; H01L 31/18

(52) U.S. Cl. 348/294; 438/69; 257/E31.127

(57) ABSTRACT

A solid-state imaging device according o an implementation of the present invention includes a plurality of unit pixels arranged in rows and columns. The unit pixels each include a photodiode which performs photoelectric conversion, a top lens which collects light, and an intralayer lens which collects, onto the photodiode, the light collected by the top lens. A centroid of the photodiode is displaced from the center of the unit pixel in a first direction. The center of the top lens is displaced from the center of the unit pixel in the first direction. A centroid of the intralayer lens is displaced from the center of the unit pixel in the first direction.

### CROSS REFERENCE TO RELATED APPLICATION

This is a continuation application of PCT application No. PCT/JP2009/001328 filed on Mar. 25, 2009, designating the United States of America.

### BACKGROUND OF THE INVENTION

(1) Field of the Invention

The present invention relates to a solid-state imaging device and a method of manufacturing the same, and relates particularly to a solid-state imaging device including pixels arranged in rows and columns.

(2) Description of the Related Art

Image sensors generally known as solid-state imaging devices include complementary metal oxide semiconductor (CMOS) image sensors and charged coupled device (CCD) image sensors. A process of manufacturing CMOS image sensors is similar to a process of manufacturing CMOS LSIs, and CMOS image sensors therefore have an advantage over CCD image sensors that a plurality of circuits can be built on a single chip. For example, a CMOS image sensor may have an A-D conversion circuit and a timing generator built on a single chip.

On the other hand, there may be difficulty in securing excellent sensitivity properties because photodiodes of CMOS image sensors have a smaller amount of incident light than those of CCD image sensors.

This is because, in CMOS image sensors, light is blocked by metal lines in wiring layers (usually two to four layers) which are necessary for CMOS image sensors to have a plurality of circuit on a single chip. Photodiodes thus have less incident light thereon.

A structure is presented which allows more efficient collection of incident light using two lenses formed above a photodiode (see Japanese Unexamined Patent Application Publication No. 2006-114592, for example).

A conventional solid-state imaging device is hereafter described.

FIG. 17 shows a circuit configuration of a unit pixel of a conventional solid-state imaging device.

A solid-state imaging device 500 shown in FIG. 17 includes a unit pixel 510, a horizontal selection transistor 123, a vertical scanning circuit 140, and a horizontal scanning circuit 141. Although FIG. 17 shows only one unit pixel 510, the solid-state imaging device 500 includes a plurality of unit pixels 510 arranged in rows and columns.

The unit pixels 510 each include a photodiode 111, a charge-transfer gate 112, a floating diffusion (FD) region 114, a reset transistor 120, a vertical selection transistor 121, and an amplifier transistor 122.

The photodiode 111 is a photoelectric conversion unit which converts incident light on signal charges (electrons) and accumulates the signal charges resulting from such conversion.

The charge-transfer gate 112 has a gate electrode connected to a read signal line 113. The charge-transfer gate 112 transfers the signal charges accumulated in the photodiode 111 to the FD region 114 according to a read pulse applied to the read signal line 113.

The FD region 114 is connected to a gate electrode of the amplifier transistor 122.

The amplifier transistor 122 impedance-converts potential change of the FD region 114 into a voltage signal and provides the voltage signal resulting from the impedance conversion to a vertical signal line 133.

The vertical selection transistor 121 has a gate electrode connected to a corresponding one of vertical selection lines 131. The vertical selection transistor 121 switches between on and off according to a vertical selection pulse applied to the corresponding vertical selection line 131, thereby driving the amplifier transistor 122 for a predetermined period of time.

The reset transistor 120 has a gate electrode, which is connected to a vertical reset line 130. The reset transistor 120 resets the potential of the FD region 114 to the potential of a power line 132 according to a vertical reset pulse applied to the vertical reset line 130.

The vertical scanning circuit 140 and the horizontal scanning circuit 141 scan the unit pixels 510 so that each of the unit pixels 510 is selected once in one cycle.

Specifically, the vertical scanning circuit 140 provides a vertical selection pulse to one of the vertical selection lines 131 to select the unit pixels 510 in a row corresponding to the vertical selection line 131 for a predetermined period of time in one cycle. Output signals (voltage signals) are provided from the selected unit pixels 510 to the respective vertical signal lines 133.

The horizontal scanning circuit 141 provides horizontal selection pulses to horizontal selection lines 134 in sequence within the predetermined period of time to select each of the horizontal selection transistors 123.

When selected, each of the horizontal selection transistors 123 transmits the output signal of the vertical signal line 133 connected to the selected horizontal selection transistor 123 to a horizontal signal line 135.

When the horizontal scanning circuit 141 finishes selecting all the unit pixels 510 in a row, the vertical scanning circuit 140 provides a vertical selection pulse to the vertical selection line 131 corresponding to the next row. Subsequently, pixels in the next row are scanned in the above-described manner.

This operation is repeated so that all the unit pixels 510 are scanned and each of the unit pixels 510 is selected once in a cycle, and thus output signals from all the unit pixels 510 are sequentially transmitted to the horizontal signal line 135.

FIG. 18 is a cross-sectional view showing a configuration of an imaging area of the conventional solid-state imaging device 500.

FIG. 19 is a schematic view showing connections between components of the unit pixel 510.

As shown in FIG. 18, the solid-state imaging device 500 includes a semiconductor substrate 201, an insulation layer 202, wirings 203A to 203C, light-shielding films 204A and 204B, a passivation film 205, intralayer lenses 606, a planarization film 207, color filters 208, and top lenses 610.

The photodiodes 111 and the FD regions 114 are formed in the semiconductor substrate 201 and the charge-transfer gates 112 on the semiconductor substrate 201.

The insulation layer 202 is formed on the semiconductor substrate 201. The wirings 203A to 203C in layers are formed in the insulation layer 202. The wirings 203A to 203C are made of, for example, aluminum.

The light-shielding films 204A and 204B, which are formed on the wiring 203A and the wiring 203B, respectively, prevent light incidence into a circuitry part including transistors. Incident light 310 leaking into the circuitry part causes photoelectric conversion. Electrons resulting from the photoelectric conversion generate aliasing to be noise. The light-shielding films 204A and 204B are provided in order to reduce such noise.

The passivation film 205, which is formed on the insulation layer 202, is made of, for example, silicon nitride.

The intralayer lenses 606 are formed on the passivation film 205.

The planarization film 207, which is formed on the intralayer lenses 606, is made of, for example, silicon oxide.

The color filters 208 are formed on the planarization film 207.

The top lenses 610 are on-chip lenses formed above the color filter 208.

As shown in FIG. 19, an n-type impurity layer in which the photodiodes 111, the FD region 114, and the reset transistor 120 are formed is provided in a manner such that the photodiodes 111, the FD region 114, and the reset transistor 120 are connected through channel regions below gate electrodes. This configuration allows efficient transfer and erasure of signal charges.

The top lenses 610 and the intralayer lenses 606 collect incident light 310 onto the photodiode 111. The top lenses 610 are formed with an equal pitch and at regular intervals. The intralayer lenses 606 are also formed with an equal pitch and at regular intervals.

Here, in the conventional solid-state imaging device 500, the unit pixels 510 share relative positions of the photodiodes 111, the charge-transfer gates 112, the FD regions 114, the reset transistor 120, the vertical selection transistor 121, the amplifier transistor 122, the wiring within the pixel, the top lenses 610, and the intralayer lenses 606. In other words, each type of these components are arranged with a regular pitch to have translation symmetry. As a result, the incident light 310 falls on the photodiodes 111 of all the unit pixels in the same manner, so that an image obtained is of good quality with small unevenness among the unit pixels 510.

For amplifier-type solid-state imaging devices such as CMOS image sensors, wirings need to be layered in at least two layers, or preferably in three or more layers as described above. A structure formed on the photodiode 111 therefore tends to be thick. For example, the height from the top surface of the photodiode 111 to the uppermost layer, that is, the third layer, 203C is 3 to 5 μm, which is as large as one of dimensions of a pixel.

This causes a problem with a solid-state imaging device which images a subject after forming an image of the subject using a lens. The problem is that there is large shading in a region near the periphery of an imaging area. In other words, the light-shielding films 204A and 204B and the wirings 203A to 203C block oblique incident light, so that the amount of light collected onto the photodiode 111 is reduced. This causes a problem of significant deterioration in image quality.

There is a known technique for reducing such shading in the region near the periphery of the imaging area by correcting positions of the top lenses 610 and the openings of the light-shielding films 204A and 204B, so that oblique incident light is also collected onto the photodiode 111. This correction is called pupil correction. Specifically, the top lenses 610 and the openings of the light-shielding films 204A and 204B are displaced in a direction from which the light enters as seen from the photodiode 111.

In addition, in order to prevent decrease in the amount of incident light on the photodiode 111, a technique is employed in which decrease in the area of the photodiode 111 is reduced by reducing the area of the transistors in the unit pixel 510. However, this method has a limitation to retainment of properties of the solid-state imaging device.

On the other hand, a solid-state imaging device is presented which has a multi-pixel one-cell structure, where the unit pixels 510 each include the photodiode 111 and the charge-transfer gate 112, which are essential to each of the unit pixels 510, and adjacent ones of the unit pixels 510 share the FD region 114, the amplifier transistor 122, the vertical selection transistor 121, and the reset transistor 120, which have been conventionally provided in each of the unit pixels 510. A solid-state imaging device having the multi-pixel one-cell structure needs fewer transistors and wirings per unit pixel. This technique secures a sufficient area of the photodiode 111 and reduces vignetting caused by wirings, thus providing an effective solution to a problem in size reduction of unit pixels.

### SUMMARY OF THE INVENTION

However, the photodiodes 111 in the multi-pixel one-cell structure are not arranged with a regular pitch. Because of this, the center of light incident on each of the photodiodes 111 does not coincide with the center of the photodiode 111. This decreases the amount of incident light, and therefore sensitivity deteriorates. Furthermore, difference in angles of the incident light causes unevenness in the amount of incident light on the photodiodes 111 among the unit pixels 510. This causes unevenness among signal outputs from the respective unit pixels 510. In other words, this causes a problem of unevenness in sensitivity among pixels.

In order to address this problem, the present invention has an object of providing a solid-state imaging device in which unevenness in sensitivity among pixels is reduced, and providing a method of manufacturing the solid-state imaging device.

In order to achieve the object, the solid-state imaging device according to an aspect of the present invention is a solid-state imaging device includes a plurality of pixels arranged in rows and columns, wherein each of the pixels includes: a photoelectric conversion unit configured to perform photoelectric conversion to convert light into an electric signal; a first lens which collects incident light; and a second lens which collects, onto the photoelectric conversion unit, the incident light collected by the first lens, a light-receiving face of the photoelectric conversion unit has an effective center displaced from a pixel center in a first direction, the first lens has a center displaced from the pixel center in the first direction, and the second lens has a focal position displaced from the pixel center in the first direction.

In this configuration, the center of the first lens and the focal position of the second lens are displaced from the pixel center toward the effective center of the light-receiving face of the photoelectric conversion unit. This allows the solid-state imaging device according an aspect of the present invention to have an increased amount of incident light on the photoelectric conversion unit.

Furthermore, even in the case where photoelectric conversion units are not arranged with a regular pitch, that is, where relative positions of photoelectric conversion units are different among pixels, shifting the center of the first lens and the focal position of the second lens to the effective center of the light-receiving face of each of the photoelectric conversion units reduces unevenness among the pixels in the amount of incident light on the photoelectric conversion units. In other words, unevenness in sensitivity among the pixels is reduced in the solid-state imaging device according to the present invention.

Furthermore, each of the pixels may further include a gate electrode which covers a part of the photoelectric conversion unit and transfers the electric signal resulting from the photoelectric conversion by the photoelectric conversion unit, and the first direction may be opposite to a direction in which the gate electrode is placed, with respect to the photoelectric conversion unit.

With this configuration, even in the case where the effective centers of the light-receiving faces of the photoelectric conversion units are different among the pixels due to difference of positions of the gate electrodes among the pixels, unevenness among the pixels in the amount of incident light on the photoelectric conversion units is reduced.

Furthermore, the first lens included in each of the pixels may have the same shape.

Furthermore, the first direction may be a direction of a diagonal of each of the pixels.

With this configuration, the solid-state imaging device according to an aspect of the present invention has the first lens having the focal position displaced in the first direction, while decrease in the area of the first lens due to this displacement is reduced.

Furthermore, the second lens included in each of the pixels may have the same shape and be placed in a manner such that a center of the second lens is displaced from the center of the pixel in the first direction.

With this configuration, the focal position of the second lens, which even has the same shape as conventional ones, is displaced.

Furthermore, the center of the first lens may be displaced from the pixel center in the first direction by a distance equivalent to half a length of a region in a gate length direction of the gate electrode, the region being an overlap where the gate electrode covers the part of the photoelectric conversion unit, and the focal position of the second lens may be displaced from the pixel center in the first direction by a distance equivalent to half the length of the region in the gate length direction, the region being the overlap where the gate electrode covers the part of the photoelectric conversion unit.

With this configuration, the focal positions of the first lens and the second lens are shifted to approximately coincide with the effective center of the light-receiving face of the photoelectric conversion unit.

Furthermore, the first lens may have such an asymmetric shape that the focal position of the first lens is displaced from the pixel center in the first direction.

With this configuration, the solid-state imaging device according to an aspect of the present invention has the first lens having such an asymmetric shape that decrease in the area of the first lens due to shifting of the focal position is decreased.

Furthermore, the first lens may be symmetric with respect to a plane which contains the pixel center and is perpendicular to a top surface of the photoelectric conversion unit and located along the first direction and, and be asymmetric with respect to a plane which is perpendicular to the top surface of the photoelectric conversion unit and the first direction and contains the pixel center.

Furthermore, in each of the pixels, a region in which the first lens is not formed and which is at an edge in a direction opposite to the first direction with respect to the pixel center may be larger than a region in which the first lens is not formed and which is at an edge in the first direction with respect to the pixel center.

Furthermore, the pixels include a first pixel and a second pixel, and the first direction of the first pixel and the first direction of the second pixel may be different from each other.

Furthermore, the pixels may be included in cells having a multi-pixel one-cell structure, and each of the cells may include the first pixel and the second pixel.

Furthermore, in each of the pixels, the photoelectric conversion unit may be placed according to a first placement cell, and the first lens and the second lens may be placed according to a second placement cell, in a pixel array in which the pixels are arranged in rows and columns, a center of the second placement cell may be displaced further toward a center of the pixel array with respect to the center of the first placement cell as the second placement cell is farther from the center of the pixel array and closer to a periphery of the pixel array, the effective center of the light-receiving face of the photoelectric conversion unit may be displaced from the center of the first placement cell in the first direction, the center of the first lens may be displaced from the center of the second placement cell in the first direction, and the second lens may have the focal position displaced from the center of the second placement cell in the first direction.

This configuration reduces decrease in the amount of incident light on the photoelectric conversion unit in the pixels in the periphery of the pixel array.

Furthermore, the first lens may be made of an acrylic resin.

Furthermore, the second lens may be made of silicon nitride or silicon oxynitride.

Furthermore, a method of manufacturing a solid-state imaging device according to an aspect of the present invention is a method of manufacturing a solid-state imaging device including a plurality of pixels arranged in rows and columns, each of the pixels including: a photoelectric conversion unit which performs photoelectric conversion to convert light into an electric signal; a first lens which collects incident light; and a second lens which collects, onto the photoelectric conversion unit, the incident light collected by the first lens, and the method may include: forming the photoelectric conversion unit which has a light-receiving face having an effective center displaced from a pixel center in a first direction; forming the second lens having a focal position displaced from the pixel center in the first direction; and forming the first lens having a center displaced from the pixel center in the first direction.

With this configuration, the focal positions of the first lens and the second lens are displaced from the pixel center toward the effective center of the light-receiving face of the photoelectric conversion unit. This allows the solid-state imaging device manufactured using the method according to an aspect of the present invention to have an increased amount of incident light on the photoelectric conversion unit.

Furthermore, even in the case where photoelectric conversion units are not arranged with a regular pitch, that is, where the relative positions of photoelectric conversion units are different among pixels, displacing the focal positions of the first lens and the second lens toward the effective center of the light-receiving face of each of the photoelectric conversion units reduces unevenness among pixels in the amount of incident light on the photoelectric conversion units. In other words, unevenness in sensitivity among the pixels is reduced in the solid-state imaging device manufactured using the method according to an aspect of the present invention.

Furthermore, the forming of the first lens may include: pattering a material for the first lens; and reflowing the patterned material so as to form the first lens having an asymmetric shape and a convex surface.

Furthermore, in the patterning, the material for the first lens may be patterned using a mask which is axisymmetric with respect to a centerline containing the pixel center and extending in the first direction and is asymmetric with respect to a centerline containing the pixel center and extending orthogonally to the first direction.

Furthermore, in the patterning, the material for the first lens is patterned, using the mask, into a pentagon formed by cutting off one of corners of a rectangle, and the corner cut off from the rectangle is located in a direction opposite to the first direction with respect to the pixel center.

With this configuration, the solid-state imaging device manufactured using the method according to an aspect of the present invention has the first lens having such an asymmetric shape that decrease in the area of the first lens due to displacement of the focal position is reduced. Furthermore, this facilitates manufacture of the first lens having an asymmetric shape.

The present invention thus provides a solid-state imaging device having reduced unevenness in sensitivity among pixels, and a method of manufacturing the solid-state imaging device.

Further Information about Technical Background to this Application

The disclosure of Japanese Patent Application No. 2008-140112 filed on May 28, 2008 including specification, drawings and claims is incorporated herein by reference in its entirety.

The disclosure of PCT application No. PCT/JP2009/001328 filed on Mar. 25, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a circuit diagram showing a configuration of a unit cell of the solid-state imaging device according to Embodiment 1 of the present invention;

FIG. 2 is a plan view of an imaging area of the solid-state imaging device according to Embodiment 1 of the present invention;

FIG. 3 is a cross-sectional view of the solid-state imaging device according to Embodiment 1 of the present invention;

FIG. 4 is a plan view showing an exemplary arrangement of the photodiodes of the solid-state imaging device according to Embodiment 1 of the present invention;

FIG. 5 is a plan view showing an exemplary arrangement of the top lenses of the solid-state imaging device according to Embodiment 1 of the present invention;

FIG. 6 is a plan view showing an exemplary arrangement of the intralayer lenses of the solid-state imaging device according to Embodiment 1 of the present invention;

FIG. 7A is a diagram for describing method of manufacturing the intralayer lenses of the solid-state imaging device according to Embodiment 1 of the present invention;

FIG. 7B a diagram for describing the method of manufacturing the intralayer lenses of the solid-state imaging device according to Embodiment 1 of the present invention;

FIG. 7C a diagram for describing the method of manufacturing the intralayer lenses of the solid-state imaging device according to Embodiment 1 of the present invention;

FIG. 8A a diagram for describing a method of manufacturing the top lenses of the solid-state imaging device according to Embodiment 1 of the present invention;

FIG. 8B a diagram for describing the method of manufacturing the top lenses of the solid-state imaging device according to Embodiment 1 of the present invention;

FIG. 9 is a plan view of a variation of the solid-state imaging device according to Embodiment 1 of the present invention;

FIG. 10 is a cross-sectional view of a solid-state imaging device according to Embodiment 2 of the present invention;

FIG. 11A is a plan view showing an exemplary arrangement of the top lenses of the solid-state imaging device according to Embodiment 2 of the present invention;

FIG. 11B is a plan view showing an exemplary arrangement of the top lenses of a variation of the solid-state imaging device according to Embodiment 2 of the present invention;

FIG. 12A is a plan view showing a resist pattern to be used for forming the top lenses in the solid-state imaging device according to Embodiment 2 of the present invention;

FIG. 12B is a plan view showing the top lenses in the solid-state imaging device according to Embodiment 2 of the present invention;

FIG. 13A shows a method of manufacturing the top lenses of the solid-state imaging device according to Embodiment 2 of the present invention;

FIG. 13B shows the method of manufacturing the top lenses of the solid-state imaging device according to Embodiment 2 of the present invention;

FIG. 14 shows a schematic configuration of a solid-state imaging device according to Embodiment 3 of the present invention;

FIG. 15 is a plan view showing an arrangement of intralayer lenses and top lenses in a pixel array according to Embodiment 3 of the present invention;

FIG. 16 is a cross-sectional view of a peripheral portion of the pixel array of the solid-state imaging device according to Embodiment 3 of the present invention;

FIG. 17 shows a circuit configuration of a unit pixel of a conventional solid-state imaging device;

FIG. 18 is a cross-sectional view showing a configuration of an imaging area of the conventional solid-state imaging device; and

FIG. 19 shows a schematic view showing connections between components of a unit pixel of a conventional solid-state imaging device.

### DESCRIPTION OF THE PREFERRED EMBODIMENTS

Hereinafter, a solid-state imaging device according to embodiments of the present invention is described with reference to the drawings.

### Embodiment 1

In each unit pixel of a solid-state imaging device according to Embodiment 1 of the present invention, focal positions of a top lens and an intralayer lens coincide with an effective center of a light-receiving face of a photodiode. This reduces unevenness in sensitivity among the pixels of the solid-state imaging device according to Embodiment 1 of the present invention.

The solid-state imaging device according to Embodiment 1 of the present invention is a MOS image sensor (CMOS image sensor). A solid-state imaging device 100 according to Embodiment 1 of the present invention has a four-pixel one-cell structure.

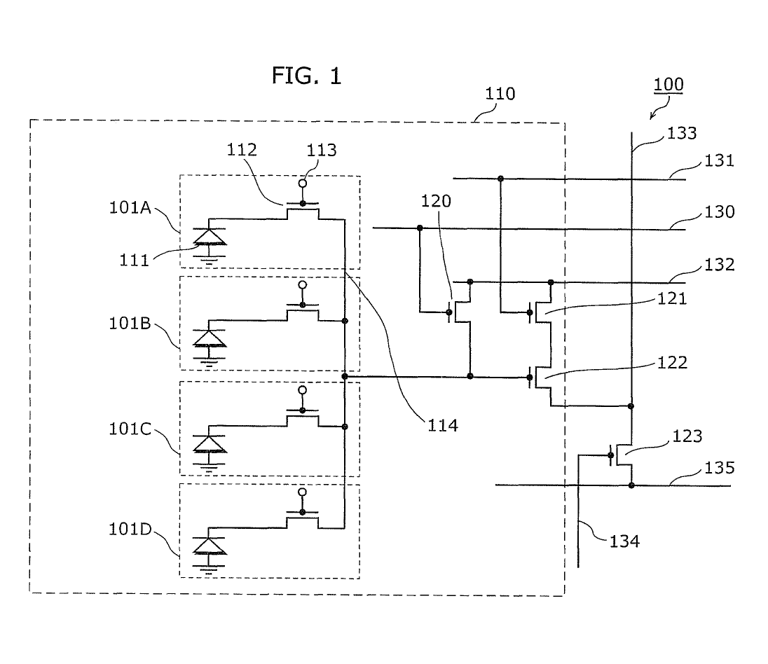

FIG. 1 is a circuit diagram showing a structure of a unit cell 110 of the solid-state imaging device 100 according to Embodiment 1 of the present invention.

The unit cell 110 includes four unit pixels 101A to 101D, a reset transistor 120, a vertical selection transistor 121, and an amplifier transistor 122. The four unit pixels 101A to 101D are referred to as unit pixels 101 when they are mentioned with no specific distinction.

The unit cell 110 shown in FIG. 1 includes an FD 114 which is commonly connected to the four unit pixels 101A to 101D. The reset transistor 120, the vertical selection transistor 121, and the amplifier transistor 122 are shared by the four unit pixels 101A to 101D.

Each of the unit pixels 101A to 101D has a photodiode 111 and a charge-transfer gate 112.

The photodiode 111 is a photoelectric conversion unit which converts incident light into signal charges (electrons) and accumulates the signal charges resulting from the conversion.

The charge-transfer gate 112 has a gate electrode, which is connected to a read signal line 113. The charge-transfer gate 112 is a transistor which transfers the signal charges accumulated in the photodiode 111 to the FD region 114 according to a read pulse applied to the read signal line 113.

The FD region 114 is connected to a drain of the charge-transfer gate 112 of each of the four unit pixels 101A to 101D. The FD region 114 is connected to a gate electrode of the amplifier transistor 122.

The amplifier transistor 122 impedance-converts potential change of the FD region 114 into a voltage signal and provides the voltage signal resulting from the conversion to a vertical signal line 133.

The vertical selection transistor 121 has a gate electrode, which is connected to a corresponding one of vertical selection lines 131. The vertical selection transistor 121 switches between on and off according to a vertical selection pulse applied to the corresponding vertical selection line 131, thereby driving the amplifier transistor 122 for a predetermined period of time.

The reset transistor 120 has a gate electrode, which is connected to a vertical reset line 130. The reset transistor 120 resets the potential of the FD region 114 to the potential of a power line 132 according to a vertical reset pulse applied to the vertical reset line 130.

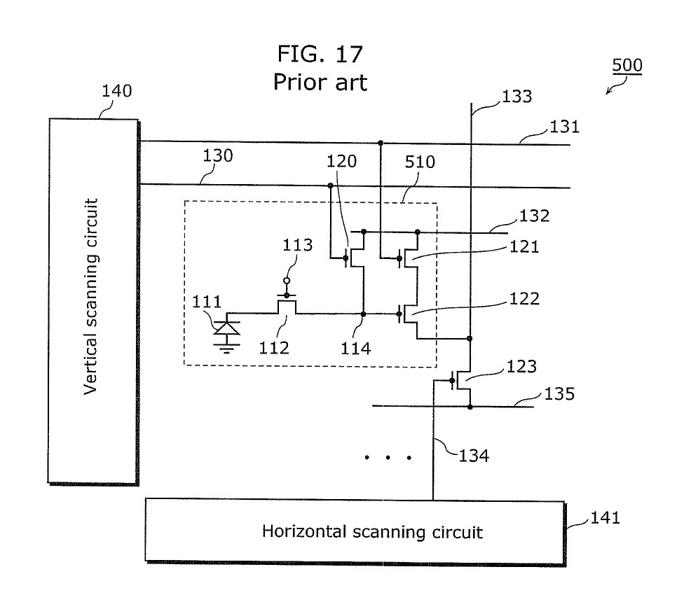

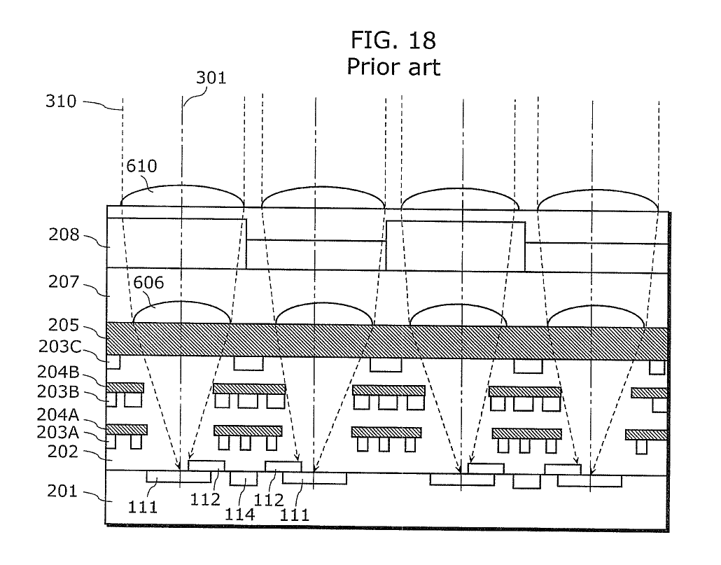

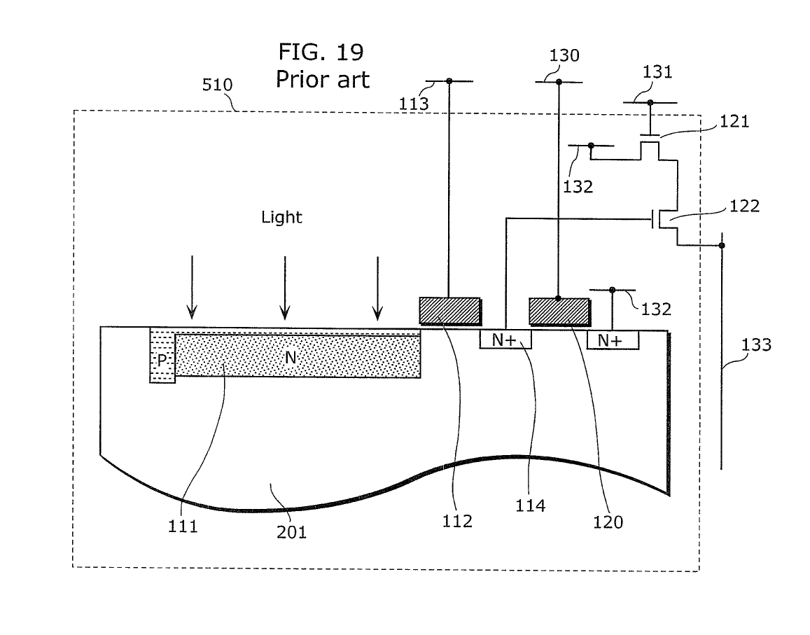

As with the solid-state imaging device 500 shown in FIG. 17, the solid-state imaging device 100 includes a vertical scanning circuit 140 and a horizontal scanning circuit 141, which are not shown in FIG. 1. The solid-state imaging device 100 includes the unit pixels 101 (and the unit cells 110) arranged in rows and columns.

The vertical scanning circuit 140 and the horizontal scanning circuit 141 scan the unit pixels 101 so that each of the unit pixels 101 is selected once in one cycle.

Specifically, the vertical scanning circuit 140 provides a vertical selection pulse to one of the vertical selection lines 131 to select one of the unit cells 110, that is, the unit pixels 101A to 101D which form a set, in a row corresponding to the vertical selection line 131 for a predetermined period of time in one cycle.

In the period of time, signal charges accumulated in the photodiodes 111 of the unit pixels 101A to 101D are sequentially transferred to the FD region 114 according to a read pulse applied to the read signal line 113. The signal charges transferred to the FD region 114 are converted into voltage signals by the amplifier transistor 122, and the voltage signals resulting from the conversion are sequentially provided to the vertical signal line 133.

The horizontal scanning circuit 141 selects respective horizontal selection transistors 123 by sequentially providing horizontal selection pulses to horizontal selection lines 134 in the predetermined period of time.

The selected horizontal selection transistor 123 transmits output signals of the vertical signal line 133 connected to the horizontal selection transistor 123 to a horizontal signal line 135.

When the horizontal scanning circuit 141 finishes scanning all the unit pixels 101 in a row, the vertical scanning circuit 140 provides a vertical selection pulse to the vertical selection line 131 corresponding to the next row. Consequently, unit pixels 101 in the next row are scanned in the above-described manner.

This operation is repeated so that all the unit pixels 101 are scanned and each of the unit pixels 101 is selected once in a cycle, and thus output signals from all the unit pixels 510 are sequentially transmitted to the horizontal signal line 135.

Use of the four-pixel one-cell structure thus reduces the number of transistors necessary per unit pixel 101. This allows the photodiodes 111 of the solid-state imaging device 100 to have a sufficient light receiving area.

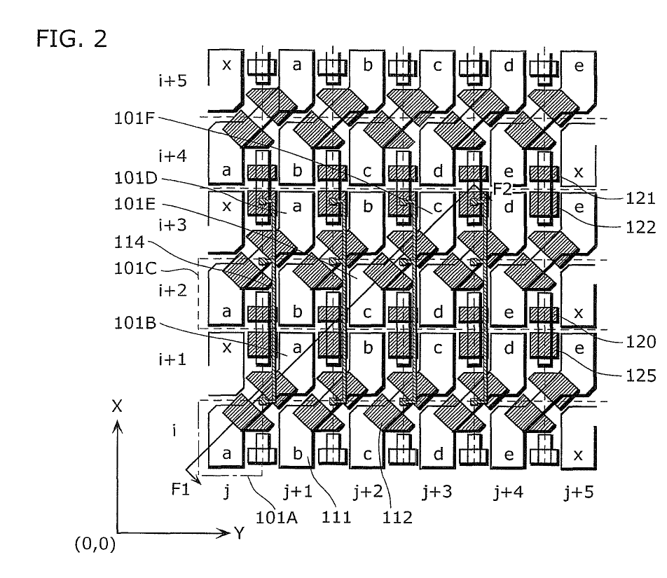

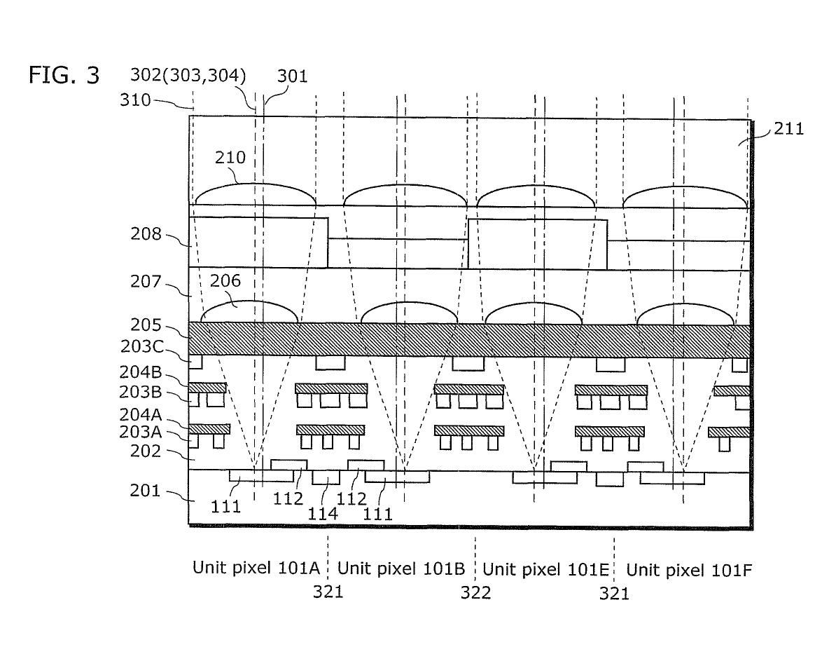

FIG. 2 is a plan view of an imaging area of the solid-state imaging device 100. FIG. 3 is a cross-sectional view of the unit pixels 101A, 101B, 101E, and 101F taken along line F1-F2 of FIG. 2.

In FIG. 2, the photodiodes 111 included in one unit pixel 101 are denoted by the same symbol (a, b, c, d . . . x). In addition, an origin (0, 0) is provided at the lower left of FIG. 2 in order to indicate the positions of the unit pixels 101, where x indicates a row-wise position (a row number) and y indicates a column-wise position (a column number).

Dummy transistors 125 shown in FIG. 2 are gate electrodes provided in order to improve optical properties of the adjacent unit pixels 101. The dummy transistors 125 are not necessary.

As shown in FIG. 3, the solid-state imaging device 100 includes a semiconductor substrate 201, an insulation layer 202, wirings 203A to 203C, light-shielding films 204A and 204B, a passivation film 205, intralayer lenses 206, a planarization film 207, color filters 208, top lenses 210, and a low-refractive film 211.

The semiconductor substrate 201 is, for example, a silicon substrate.

The insulation layer 202, which is formed on the semiconductor substrate 201, is made of, for example, silicon oxide.

The wirings 203A to 203C are made of, for example, aluminum, copper, or titanium. The wiring 203A in the first layer is a global wiring provided in order to apply a potential to substrate contacts (not shown), charge-transfer gates 112, and so on. The wiring 203B in the second layer and the wiring 203C in the third layer are used for local wirings to connect transistors between the unit pixels 101 and for global wirings such as the vertical selection lines 131 and the vertical signal lines 133.

The wirings 203A to 203C are arranged in a manner such that the areas above the photodiodes 111 are cleared as much as possible. With this, the photodiodes 111 have increased opening ratios, thus receiving more light.

The light-shielding films 204A and 204B are formed on the wiring 203A and the wiring 203B, respectively, and prevent light incidence on the circuitry part such as the transistors.

The passivation film 205, which is formed on the insulation layer 202, is a protection film made of, for example, silicon nitride.

The intralayer lenses 606 are formed on the passivation film 205, and made of a high-refractive material such as a SiN film (n is approximately 1.8 to 2) or a SiON film (n is approximately 1.55 to 1.8). The intralayer lenses 206 are upwardly convex lenses.

The planarization film 207, which is formed on the intralayer lenses 206, is made of, for example, silicon oxide.

The color filters 208, which are formed on the planarization film 207, each passes only light of a predetermined frequency range.

The top lenses 210 are on-chip lenses formed above the color filter 208. The top lenses 210 are made of an acrylic resin (n is approximately 1.5), a SiN film (n is approximately 1.8 to 2), a SiON film (n is approximately 1.55 to 1.8), or a fluoride resin.

The low-refractive film 211 is formed on the top lens 210. The low-refractive film 211 has a lower refractivity than the top lenses 210. For example, the reflectivity of the low-refractive film 211 is approximately 1.2 and the refractivity of the top lenses 210 is approximately 1.5. The low-refractive film 211 is made of, for example, a fluoride resin.

The top lenses 210 collect incident light 310 transmitted through the low-refractive film 211. Next, the intralayer lenses 206 collect, onto the photodiodes 111, the light collected by the top lenses 210 and transmitted through the color filter 208 and the planarization film 207.

Here, MOS image sensors have a larger number of wiring layers than CCD image sensors. This results in that a distance between the top surface of the semiconductor substrate 201 and that the intralayer lens 206 of a MOS image sensor is longer than that of a CCD image sensor, and that a distance from the top surface of the semiconductor substrate 201 and the top lens 210 of a MOS image sensor is longer than that of a CCD image sensor.

In this case, curvatures of the top lenses 210 and the intralayer lenses 206 need to be smaller. Tops lenses and intralayer lenses having large curvatures collect light to a spot above the top surface of the semiconductor substrate 201, and thus the incident light is spread on the surface of the semiconductor substrate 201. This results in insufficient light collection onto the photodiodes 111.

As usual with a 1.75-μm cell of a CCD image sensor, the intralayer lenses 206 have a height of approximately 0.7 μm and the top lenses 210 have a height of approximately 0.5 μm. A MOS image sensor with lenses of these heights would collect light at a spot far above the top surface of the semiconductor substrate 201. MOS image sensors therefore need to have the intralayer lenses 206 having a height of approximately 0.3 μm and top lenses 210 having a height of approximately 0.2 μm.

The top lenses 210 are formed using a heat flow method described later. But it is very difficult to make top lenses 210 having a height of 0.5 μm or less using the heat flow method. Thus, in order to effectively reduce the refractivity of the top lenses 210, the low-refractive film 211, which has a lower-refractivity than the top lens 210, is applied onto the top lenses 210.

The low-refractive film 211 is not necessary but preferably provided to the solid-state imaging device 100 according to the present invention.

An n-type region of the photodiode 111 and an n-type region of the FD region 114 are connected through a channel region of a corresponding one of the charge-transfer gates 112 so that signal charges are efficiently transferred therebetween. In this case, in each of the unit pixels 101, the center of the photodiode 111 coincides with the center 301 of the unit pixel 101, but the centroid 302 of light collected by the photodiode 111 deviates from the center 301 of the unit pixel 101 because the charge-transfer gate 112 overlaps the photodiode 111.

As a result, long pitches (segments each including a boundary position 321) and short pitches (segments each including a boundary position 322) alternate in the sequence of the centroids 302 of the photodiodes 111. For example, as shown in FIG. 3, since the unit pixel 101A and the unit pixel 101B share the FD region 114 at the boundary position 321, the pitch between the centroids 302 of the photodiodes 111 is a long pitch. On the other hand, since the unit pixel 101B and the unit pixel 101C do not share the FD region 114 at the boundary position 322, the pitch between the photodiodes 111 is a short pitch.

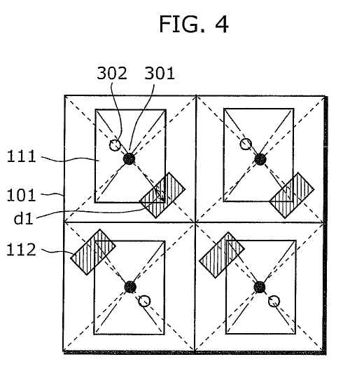

FIG. 4 is a plan view showing an exemplary arrangement of the photodiodes 111 in the unit pixels 101.

The photodiodes 111 are rectangles having short sides of 900 nm and long sides of 1550 nm. The unit pixels 101 are separated by an isolation region having a width of 200 to 300 nm.

The charge-transfer gates 112 are obliquely provided to respective photodiodes 111 to provide a channel which transfer signal charges from the photodiodes 111 to the FD regions 114. The charge-transfer gates 112 have a gate length of 650 nm and a gate width of 500 nm.

In the case of the four-pixel one-cell structure, the centers 301 of the unit pixels 101 do not coincide with the centroids 302 of the respective photodiodes 111. Here, each of the centroids 302 of the photodiodes 111 is an effective center of the light-receiving face of the photodiode 111, that is, the centroid of the region, in the top surface of the photodiode 111, not covered by the charge-transfer gate 112.

To put it another way, in the case of the four-pixel one-cell structure, the charge-transfer gates 112 are arranged differently between adjacent ones of the unit pixels 101. The centroids 302 of the respective photodiodes 111 thus do not correspond to each other.

Furthermore, for example, the centers of the photodiodes 111 coincide with the respective unit pixels 101. Here, each of the centers of the photodiodes 111 is the center of the photodiode 111 including the region covered by the charge-transfer gate 112.

Although the regions of the photodiodes 111 covered by the gate electrodes 112 are reduced by shortening the gate length of the charge-transfer gates 112, this affects reading properties of the charge-transfer gates 112, causing a side effect of deterioration in after-image characteristics. The charge-transfer gates 112 thus cannot be modified with ease.

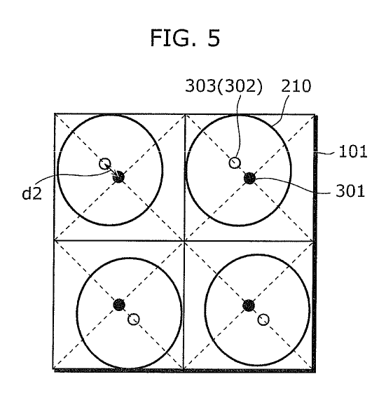

FIG. 5 is a plan view showing an exemplary arrangement of the top lenses 210.

As shown in FIG. 5, centroids 303 of the top lenses 210 coincide with the centroids 302 of the photodiodes 111. The centroids 303 of the top lenses 210 are optical centroids of the respective top lenses 210, that is, the centers (positions of focuses (light axes)) to which light perpendicular to the photodiodes 111 are collected by the respective top lenses 210. For example, in the case where the unit pixels 101 have top lenses of the same shape, the centroids 303 of the top lenses 210 are adjusted by changing the positions (of centers) of the top lenses 210 as shown in FIG. 5. For example, the positions of the top lenses 210 are displaced in the direction of displacement by 70 nm from the respective centers 301 of the unit pixels 101.

Furthermore, the shape of the top lenses 210 is symmetric with respect to the respective centroids 303 of the top lenses 210.

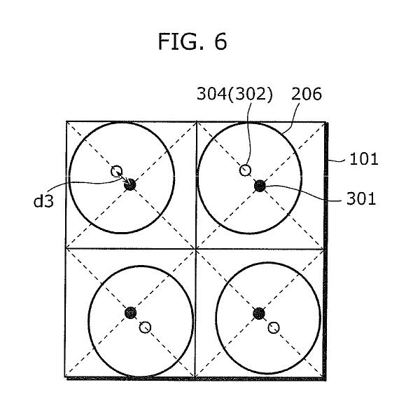

FIG. 6 is a plan view showing an exemplary arrangement of the intralayer lenses 206.

As shown in FIG. 6, centroids 304 of the intralayer lenses 206 coincide with the respective centroids 302 of the photodiodes 111. The centroids 304 of the intralayer lenses 206 are optical centroids of the respective top lenses 200, that is, the centers (positions of focuses (light axes)) to which light perpendicular to the photodiodes 111 are collected by the respective intralayer lenses 206. For example, in the case where the unit pixels 101 have intralayer lenses of the same shape, the centroids 304 of the intralayer lenses 206 are adjusted by changing the positions (of centers) of the intralayer lenses 206 as shown in FIG. 6. For example, the positions of intralayer lenses 206 are displaced in the direction of displacement by 70 nm from the respective centers 301 of the unit pixels 101.

Furthermore, the shape of the intralayer lenses 206 is symmetric with respect to the respective centroids 304 of the intralayer lenses 206.

The intralayer lenses 206 have a diameter of 1350 nm, for example, which is small in comparison with diameters (for example, 1450 nm) of conventional image sensors. The intralayer lenses 206 having a larger diameter are more preferable because they have better sensitivity properties. However, because gate electrodes in the circuitry part such as the transistors block and absorb light, the intralayer lenses 206 having a smaller diameter provide increased light-collection properties to the adjacent unit pixels 101.

Furthermore, the intralayer lenses 206 are each shaped like a quadratic curve by a heat flow method using a resist material. However, because controlling a process of heat flow is very difficult, the intralayer lenses 206 are preferably arranged with the minimum pitch therebetween of 300 nm or larger. Due to such a constraint, row-wise distances between the intralayer lenses 206 of 500 nm and 300 nm coexist. The column-wise distance between the intralayer lenses 206 is 400 nm.

The photodiode 111 of the unit pixel (i, j) 101A and the photodiode 111 of the unit pixel (i+1, j+1) 1016 are arranged centrosymmetrically with respect to the FD region 114 therebetween. Similarly, the photodiode 111 in the i-th row and the photodiode 111 in the (i+1)-th row and in the next column on the right are arranged centrosymmetrically with respect to the FD region 114 therebetween.

Accordingly, the intralayer lenses 206 and the top-lenses 210 are arranged in a manner such that their centroids 304 and 303 are displaced. Specifically, the centroids 304 of the intralayer lenses 206 and the centroids 303 of the top lenses 210 are displaced in the same direction as the direction in which the respective photodiodes 111 are displaced. In this case, the centroid 304 of the intralayer lens 206 and the centroid 303 of the top-lens 210 of the unit pixel 101 in the i-th row are displaced in a direction opposite to the direction in which the centroid 304 of the intralayer lens 206 and the centroid 303 of the top-lens 210 of unit pixel 101 in the (i+1)-th row and in the next column on the right.

That is, the pitches between the centroids 303 of the top lenses 210 and the pitches between the centroids 304 of the intralayer lenses 206 are short in the place where the pitches between the centroids 302 of the photodiodes 111 are short. Conversely, the pitches between the centroids 303 of the top lenses 210 and the pitches between the centroids 304 of the intralayer lenses 206 are long in the place where the pitches between the centroids 302 of the photodiodes 111.

Thus, the top lenses 210 and the intralayer lenses 206 of the solid-state imaging device 100 according to Embodiment 1 of the present invention are arranged in a manner such that the centroids 303 of the top lenses 210 and the centroids 304 of the intralayer lenses 206 coincide with the centroids 302 of the photodiodes 111. The incident light 310 which has entered the top lenses 210 in parallel with the light axes is therefore collected onto respective regions close to the centroids 302 of the photodiodes 111 by the top lenses 210 and the intralayer lenses 206. The solid-state imaging device 100 thus effectively collects indent light.

Furthermore, in each of the unit pixels 101, owing to the coincidence of the centroids 303 of the top lenses 210 and the centroids 304 of the intralayer lenses 204 with the centroids 302 of the photodiodes 111, less of the light collected by the top lenses 210 and the intralayer lenses 206 is blocked (reflected) or absorbed by the charge-transfer gates 112 on the regions shared by adjacent one of the unit pixels 101 above the semiconductor substrate 201. Unevenness of the amount of incident light among the unit pixels 101 is thus reduced. This makes sensitivity of the unit pixels 101 even and provides the solid-state imaging device 100 with preferable imaging properties. Furthermore, the solid-state imaging device 100 minimizes such vignetting so that color mixture caused by leakage of reflected light into adjacent unit pixels 101 is reduced.

Furthermore, not only the intralayer lenses 206 and the top-lenses 210 but also the wirings 203A to 203C may be displaced in accordance with the positions of the centroids 302 of the photodiodes 111. This reduces vignetting due to the wiring 203A to 203C.

It is to be noted that the centroids 303 of the top lenses 210 or the centroids 302 of the intralayer lenses 206 may not necessarily coincide with the centroids 302 of the photodiodes 111.

For example, the centroids 303 of the top lenses 210 and the centroids 304 of the intralayer lenses 206 may be displaced from the positions which coincide with the center of the photodiodes 111 (the centers 301 of the unit pixels 101) toward the respective centroids 302 of the photodiodes 111. This increases the amount of incident light on the photodiodes 111 and reduces unevenness in the sensitivity among the unit pixels 101.

In other words, in each of the unit pixels 101, the centroid 304 of the intralayer lens 206 and the centroid 303 of the top lens 210 are displaced, with respect to the center of the photodiode 111, in a direction opposite to the direction in which the charge-transfer gates 112 is present. For example, in the case shown in FIG. 4 to FIG. 6, the centroid 303 of the top lens 210 and the centroid 304 of the intralayer lens 206 in the upper left one of the unit pixels 101 are displaced along a diagonal of the unit pixel 101 in the direction opposite to the direction in which the charge-transfer gate 112 is present, that is, to the upper left of the unit pixel. Alternatively, the centroid 303 of the top lens 210 and the centroid 304 of the intralayer lens 206 may be displaced along a diagonal of the photodiode 111 in the direction opposite to the direction in which the charge-transfer gate 112 is present.

Here, where d1 is the length of the overlap of the photodiode 111 and the charge-transfer gate 112 in a direction of the channel length of the charge-transfer gate 112 (the direction of transfer of charges), the displace amount d2 of the top lens 210 from the center of the photodiode 111 (the center 301 of the unit pixel 101) and the displace amount d3 of the intralayer lens 206 from the center of the photodiode 111 are, for example, d1/2.

Hereinafter, a method of manufacturing the solid-state imaging device 100 is described.

The intralayer lenses 206 and the top lenses 210, which are characteristics of the present invention, are manufactured using a conventional method, and thus the description thereof is omitted.

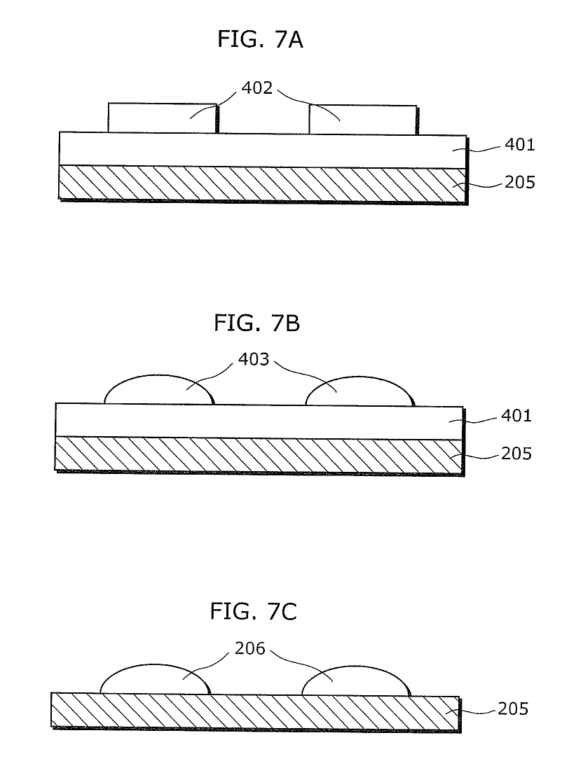

FIG. 7A to FIG. 7C show a method of manufacturing the intralayer lenses 206.

First, a silicon nitride layer 401 is formed on the passivation film 205 as shown in FIG. 7A. Next, a resist 402 is formed on the silicon nitride layer 401.

Next, a resist 403 having a convex shape is formed as shown in FIG. 7B by a resist reflow process.

Then, the intralayer lenses 206 having a convex shape are formed as shown in FIG. 7C by an etchback process.

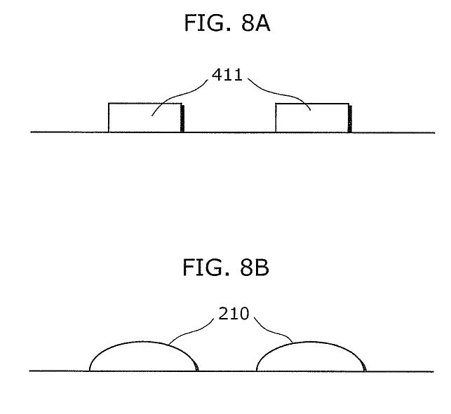

FIG. 8A and FIG. 8B show a method of manufacturing the top lenses 210.

The top lenses 210 are formed using the heat flow method.

First, a material for the lenses is provided on the planarization film on the color filters 208. The material includes an inorganic or organic, transparent material. Next, a photoresist 411 shown in FIG. 8A is formed by providing a positive resist on the lens material followed by patterning.

Next, the surface of the photoresist 411 is reflowed at a required temperature so that the surface of the photoresist 411 is curved to be convex. As a result, the top lenses 210 are formed each of which is symmetric having a convex curve as shown in FIG. 8B.

If the reflowing is performed at an excessively high temperature, the lens material completely melts to form a structure uniform in all direction with no displacement. The reflowing is thus necessarily performed at an optimum temperature (approximately 200° C.).

The present invention is not limited to the solid-state imaging device 100 according to Embodiment 1 thus far described.

For example, the intralayer lenses 206 may have a concave (downwardly convex) surface.

Furthermore, although the above description shows an example where two types of lenses of lenses, the top lenses 210 and the intralayer lenses 206 are used in the solid-state imaging device 100, a single type of lenses may be used instead. Furthermore, three or more types of lenses may be used in the solid-state imaging device 100.

Furthermore, the present invention is not limited to the solid-state imaging device 100 having the four-pixel one-cell structure as described above. For example, the solid-state imaging device 100 may have a two-pixel one-cell structure or a structure in which each cell includes more than four pixels.

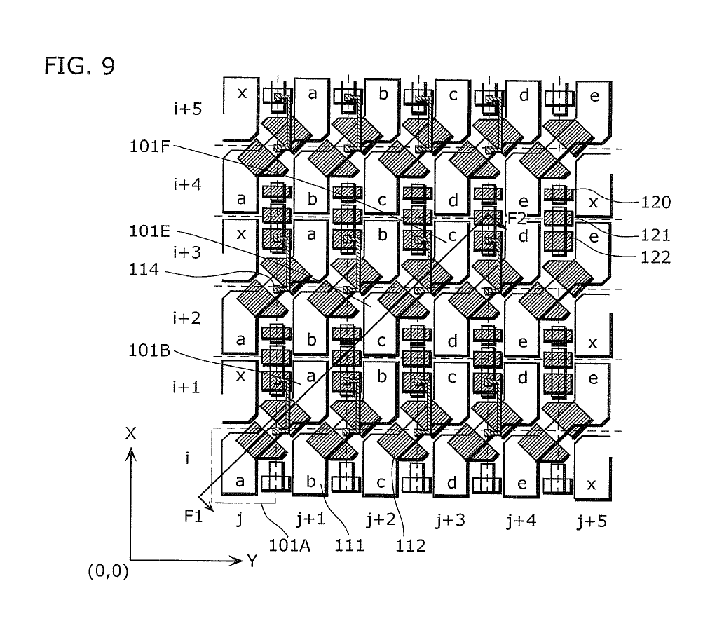

FIG. 9 is a plan view of an imaging area of the solid-state imaging device 100 having a two-pixel one-cell structure.

The two-pixel one-cell structure shown in FIG. 9 is different from the four-pixel one-cell structure shown in FIG. 2 in the layout of the amplifier transistors 122, the reset transistors 120, and the vertical selection transistors 121. Wirings in the FD regions 114 are also different.

Fine design rules are thus necessarily applied in order to provide the solid-state imaging device 100 having a two-pixel one-cell structure with an area of photodiodes 111 equivalent to that of the solid-state imaging device 100 having the four-pixel one-cell structure.

It is to be noted that the positional relationship between the photodiodes 111 and the charge-transfer gates 112 is the same as that of the four-pixel one-cell structure shown in FIG. 2. Therefore, variation among pixels in sensitivity may be reduced by displacing the centroids 304 of the intralayer lenses 206 and the centroids 303 of the top lenses 210 in the displacement direction of the photo diodes 111 in the manner as described above.

Furthermore, the present invention is applicable to CCD image sensors.

### Embodiment 2

A solid-state imaging device 100 according to Embodiment 2 of the present invention is a variation of the solid-state imaging device 100 according to Embodiment 1 of the present invention. The solid-state imaging device 100 according to Embodiment 2 of the present invention is different from the solid-state imaging device 100 according to Embodiment 1 of the present invention in that the shape of top lenses 210 is asymmetric.

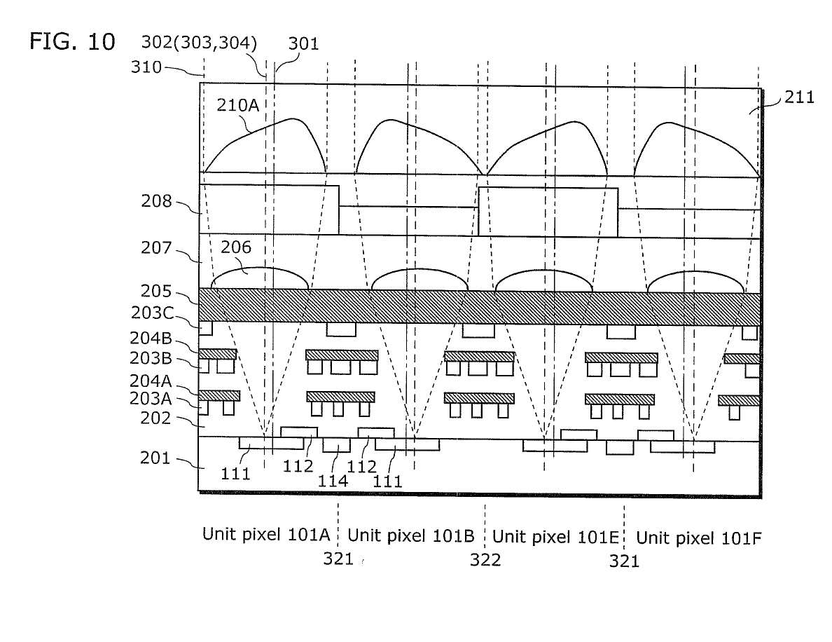

FIG. 10 is a cross-sectional view of an imaging area of a solid-state imaging device 100 according to Embodiment 2.

The solid-state imaging device 100 according to Embodiment 2 of the present invention shown in FIG. 10 is different from the solid-state imaging device 100 according to Embodiment 1 of the present invention in that top lenses 210A are provided instead of the top lenses 210.

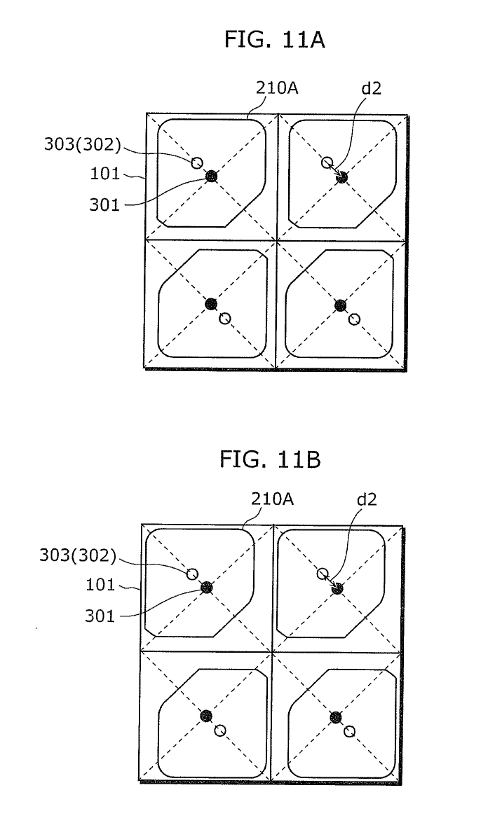

FIG. 11A is a plan view showing an exemplary arrangement of the top lenses 210A.

As shown in FIG. 11A, centroids 303 of the top lenses 210A coincide with the centroids 302 of the photodiodes 111. In unit pixels 101, (the centers of) the top lenses 210A are placed at the same positions, and the positions of the centroids 303 of the top lenses 210A are adjusted by changing shapes (orientations) of the top lenses 210A.

Specifically, the shape of each of the top lenses 210A is asymmetric with respect to a plane which contains the center 301 of the unit pixel 101 and is perpendicular to the top surface of the semiconductor substrate 201 (the photodiode 111) and to the direction in which the centroid of the top lens 210A is displaced (hereinafter referred to as a displacement direction). In addition, the shape of each of the top lenses 210A is symmetric with respect to a plane which is perpendicular to the top surface of the semiconductor substrate 201 and located along the displacement direction and contains the center of the unit pixel 101.

For an invalid region, where the top lens 210A is not formed, the invalid region on the side in the displacement direction (the direction from the center 301 of the unit pixel 101 toward the centroid 303 of the top lens 210A) is relatively small, and the invalid region on the side in a direction opposite to the displacement direction is relatively large. In other words, the invalid region at the edge in the direction opposite to the displacement direction of the unit pixel 101 is larger than the invalid region at the edge in the displacement direction.

The top lenses 210A may be changed both in shape and position.

FIG. 11B is a plan view showing an exemplary arrangement of the top lenses 210A with the shape and the positions of the top lenses 210A changed. The centers of the top lenses 210A may be displaced in the respective displacement directions and the shape of the top lenses 210A may be adjusted as shown in FIG. 11B so that the centroids 303 of the top lenses 210A coincide with the respective centroids 302 of the photodiodes 111.

The solid-state imaging device 100 according to Embodiment 2 of the present invention thus produces the same advantageous effect as the solid-state imaging device 100 according to Embodiment 1 of the present invention.

Furthermore, the top lenses 210A of the solid-state imaging device 100 according to Embodiment 2 each have an asymmetric shape so that the centroid 303 of each of the top lenses 210A is displaced in the displacement direction.

In the case where the top lenses 210 are displaced in the respective displacement directions with no change in shape, the area of each of the top lenses 210 needs to be small in comparison with the case where the top lenses 210 are placed on the respective centers 301 of the unit pixels 101 because the displacement directions are different among the adjacent ones of the unit pixels 101. On the other hand, when the top lenses 210A used in the solid-state imaging device 100 each have an asymmetric shape, the top lenses 210 need not be displaced (or the necessary amount of the displacement is smaller). Although the area of each of the top lenses 210A needs to be small for displacement of the centroids 303 of the top lenses 210A, use of such an asymmetric shape reduces reduction in the areas of the top lenses 210A of the solid-state imaging device 100.

A method of manufacturing the solid-state imaging device 100 according to Embodiment 2 is hereinafter described.

The components other than the top lenses 210A are manufactured using the same method as those of Embodiment 1, and thus the description thereof is omitted.

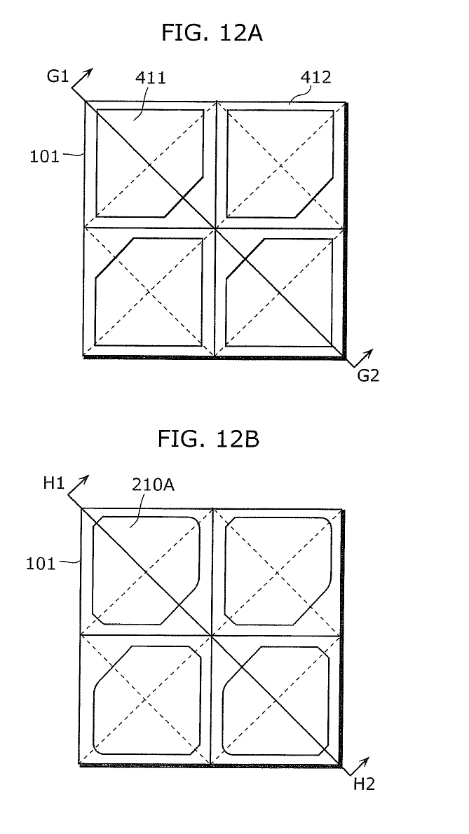

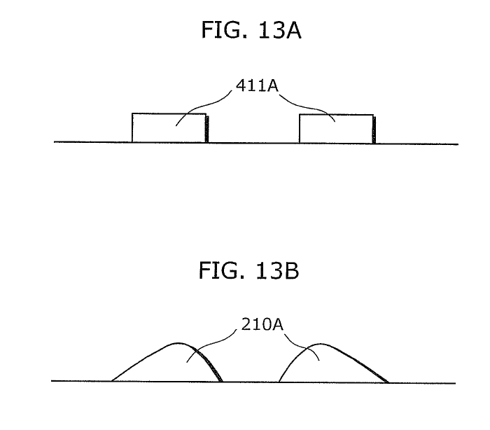

FIG. 12A, FIG. 12B, FIG. 13A, and FIG. 13B show a method of manufacturing the top lenses 210A.

FIG. 12A is a plan view showing a resist pattern to be used for forming the top lenses 210A. FIG. 13A is a cross-sectional view taken along line G1-G2 of FIG. 12A. FIG. 12B is a plan view showing the top lenses 210A formed using this manufacturing method. FIG. 13B is a cross-sectional view taken along line H1-H2 of FIG. 12B.

The top lenses 210A are formed using a heat flow method.

First, a material for the lenses is provided on the planarization film on the color filters 208. The material includes an inorganic or organic, transparent material. Next, a positive resist is provided on the formed lens material. As shown in FIG. 12A, a mask layout 412 of the positive resist is axisymmetric with respect to a centerline which contains a diagonal parallel to the displacement direction of the unit pixel 101 (that is, with respect to a line which is in the displacement direction and contains the center 301 of the unit pixel 101), and asymmetric with respect to a centerline which is a diagonal orthogonal to the displacement direction (that is, with respect to a line which is in a direction orthogonal to the displacement direction and contains the center 301 of the unit pixel 101). Specifically, the mask layout 412 has a pattern of a pentagon formed by cutting off one of corners of a square. The corner cut off from the square is located in the direction opposite to the displacement direction with respect to the center of the unit pixel 101.

A photoresist 411A shown in FIG. 13A is formed by performing patterning using the mask layout 412.

Next, the surface of the photoresist 411A is reflowed at a required temperature so that the surface of the photoresist 411A is curved to be convex. As a result, the top lenses 210A are formed each of which is asymmetric having a convex curve as shown in FIG. 12B and FIG. 13B.

If the reflowing is performed at an excessively high temperature, the lens material completely melts to form a structure uniform in all direction with no displacement. Reflowing is thus necessarily performed at an appropriate temperature (approximately 200° C.).

Conventionally, there has been a proposed method of forming an asymmetric lens. In this method, a grayscale mask is used. In the grayscale mask, unit patterns are two-dimensionally provided. Transparencies of each of the unit patterns are asymmetrically distributed therein. However, manufacturing grayscale masks requires advanced techniques and extremely high cost.

In contrast, use of the manufacturing method according to Embodiment 2 of the present invention allows manufacturing of asymmetric lenses at low cost.

It is to be noted that the intralayer lenses 206 may be changed in shape at the same positions, or may be changed both in shape and position.

### Embodiment 3

A solid-state imaging device according to Embodiment 3 of the present invention is hereinafter described. In addition to the characteristics of the solid-state imaging device 100 according to Embodiment 1, the solid-state imaging device has a characteristic that the amount of incident light in the periphery of pixel arrays is increased.

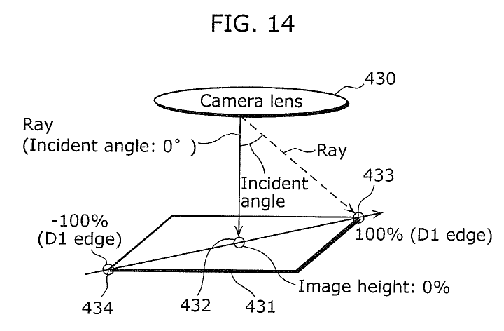

FIG. 14 shows a schematic configuration of an imaging apparatus (a camera) which includes the solid-state imaging device 100 according to Embodiment 1 of the present invention, and, in particular, a relation among a camera lens 430, a pixel array 431, and incident angle of rays.

As shown in FIG. 14, a center portion 432 of the pixel array (an imaging area) 431 has incident light which is incident at a right angle) (0°) to the semiconductor substrate 201. On the other hand, peripheral portions 433 and 434 of the pixel array 431 have oblique incident light (at approximately 25°).

With an increase in aspect ratio of a unit pixel (ratio of the opening area to the depth of the photodiode 111) with finer design rules for image sensors in recent years, the amount of oblique incident light on the peripheral portions 433 and 434 has increased.

According to Embodiment 3 of the present invention, the solid-state imaging device 100 described below has the top lenses 210, the intralayer lenses 206, and the wirings 203A to 203C which are displaced toward the center 432 of the pixel array 431, and the amount of the displacement is larger as the unit pixel 101 is farther from the center portion 432 of the pixel array 431 and closer to the peripheral portions such as 433 and 434 which have relatively more oblique incident light.

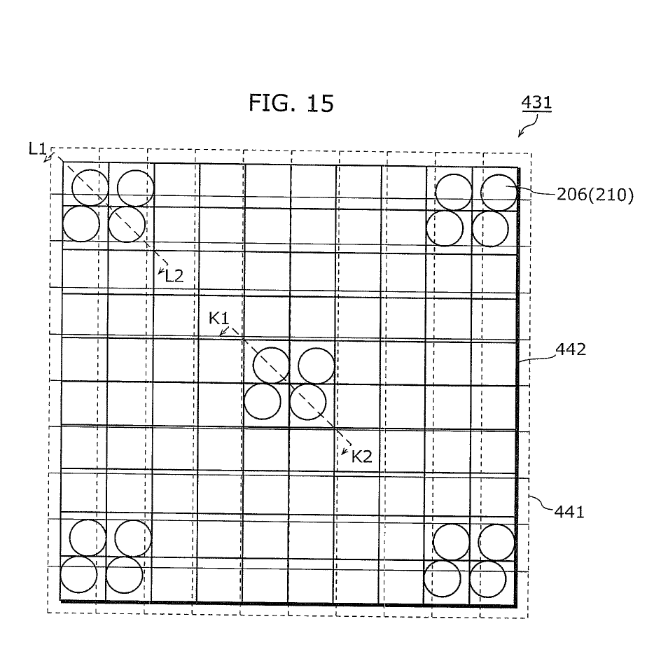

FIG. 15 is a plan view showing an arrangement of the intralayer lens 206 and the top lenses 210 in the pixel array 431.

First placement cells 441 shown in FIG. 15 are each a unit cell for components (such as the photodiode 111 and the charge-transfer gate 112) included in lower layers of the unit pixel 101. Second placement cells 442 are each a unit cell for components (such as the top lens 210, the intralayer lens 206, and the wirings 203A to 203 C) included in upper layers of the unit pixel 101.

In other words, in each of the unit pixels 101, the components in the lower layers are placed according to the first placement cell 441, and the components in the upper layers are placed according to the second placement cell 442.

As shown in FIG. 15, in each of the unit pixels 101, the first placement cell 441 and the second placement cell 442 coincide with each other in the central portion of the pixel array 431. On the other hand, the center of the second placement cell 442 is displaced further toward the center of the pixel array 431 with respect to the center of the first placement cell as the second placement cell 442 is farther from the center of the pixel array 431 and closer to the periphery of the pixel array 431. In other words, the intralayer lenses 206 and the top lenses 210 closer to the periphery of the pixel array 431 are displaced further toward the center of the pixel array 431.

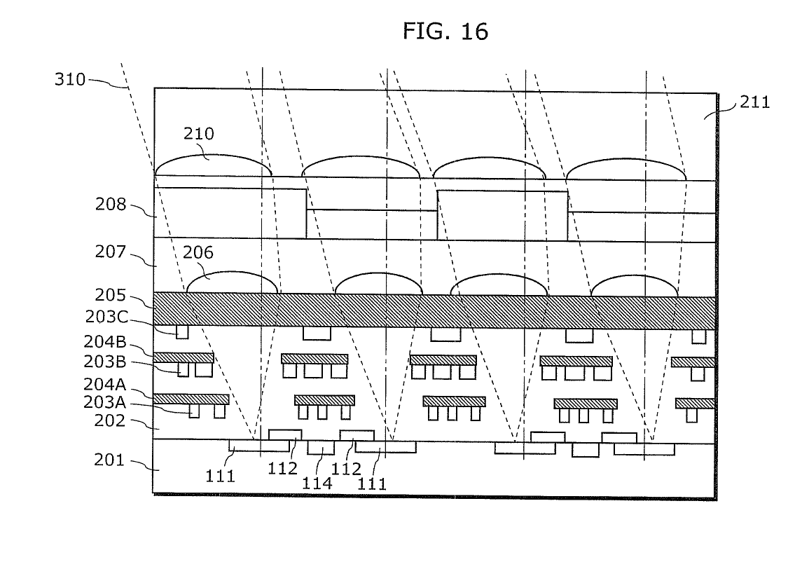

FIG. 16 is a cross-sectional view of the periphery of the pixel array 431, taken along near a line L1-L2 of FIG. 15. A cross-sectional view of the central portion of the pixel array 431 taken along near a line K1-K2 of FIG. 15 is similar to the cross-sectional view shown in FIG. 3.

As shown in FIG. 16, the intralayer lenses 206 and the top lenses 210 displaced toward the center of the pixel array 431 allow incidence of more oblique light on the centroids of the photodiodes 111. The solid-state imaging device 100 according to Embodiment 3 of the present invention thus has an increased efficiency of collection of light.

It is to be noted that, as described in Embodiment 1, in the solid-state imaging device 100 according to the present invention, the centroids 304 of the intralayer lenses 206 and the centroids 303 of the top lenses 210 are the displaced toward the centroids 302 of the photodiodes 111. In other words, in the unit pixels 101, the centroids 302 of the photodiodes 111 are displaced from the center of the first placement cells in the displacement directions, the top lenses 210 are formed in a manner such that the centroids 303 are displaced from the center of the second placement cells 442 of the unit pixels 101 in the displacement directions, and the intralayer lenses 206 are formed in a manner such that the centroids 304 are displaced from the center of the second cells 442 in the displacement directions.

With this configuration, the intralayer lenses 206 and the top lenses 210 are placed with displacements of a larger amount and a smaller amount, which alternate every row, toward the center of the pixel array 431.

It is to be noted that the top lenses 210A, the intralayer lenses 206, and the wirings 203A to 203C of the solid-state imaging device 100 according to Embodiment 2 may be displaced further from the respective centers 301 of the unit pixels 101 toward the center 432 of the pixel array 431 as they are farther from the central portion 432 of the pixel array 431 and closer to the peripheral portions such as 433 and 434.

Furthermore, although the top lenses 210 in the cases above are displaced further toward the center 432 as the top lenses 210 are farther from the central portion and closer to peripheral portions of the pixel array 431, it is also possible to displace the centroids 303 of the top lenses 210 toward the center 432 of the pixel array 431 by adjusting the shape of the top lenses 210 or the top lenses 210A. Furthermore, both the shape and positions of the top lenses 210 may be adjusted.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to solid-state imaging devices, and particularly to camcorders, digital still cameras, and facscimiles.

What is claimed is:

1. A solid-state imaging device comprising a plurality of pixels arranged in rows and columns,
wherein each of said pixels includes:
a photoelectric conversion unit configured to perform photoelectric conversion to convert light into an electric signal;
a first lens which collects incident light; and
a second lens which collects, onto said photoelectric conversion unit, the incident light collected by said first lens,
a light-receiving face of said photoelectric conversion unit has an effective center displaced from a pixel center in a first direction,
said first lens has a center displaced from the pixel center in the first direction, and
said second lens has a focal position displaced from the pixel center in the first direction.

2. The solid-state imaging device according to claim 1,
wherein each of said pixels further includes a gate electrode which covers a part of said photoelectric conversion unit and transfers the electric signal resulting from the photoelectric conversion by said photoelectric conversion unit, and
the first direction is opposite to a direction in which said gate electrode is placed, with respect to said photoelectric conversion unit.

3. The solid-state imaging device according to claim 1,
wherein said first lens included in each of said pixels has a same shape.

4. The solid-state imaging device according to claim 1,
wherein the first direction is a direction of a diagonal of each of said pixels.

5. The solid-state imaging device according to claim 1,
wherein said second lens included in each of said pixels has a same shape and is placed in a manner such that a center of said second lens is displaced from the center of said pixel in the first direction.

6. The solid-state imaging device according to claim 2,
wherein the center of said first lens is displaced from the pixel center in the first direction by a distance equivalent to half a length of a region in a gate length direction of said gate electrode, the region being an overlap where said gate electrode covers the part of said photoelectric conversion unit, and
the focal position of said second lens is displaced from the pixel center in the first direction by a distance equivalent to half the length of the region in the gate length direction, the region being the overlap where said gate electrode covers the part of said photoelectric conversion unit.

7. The solid-state imaging device according to claim 1,
wherein said first lens has such an asymmetric shape that the focal position of said first lens is displaced from the pixel center in the first direction.

8. The solid-state imaging device according to claim 7,
wherein said first lens is symmetric with respect to a plane which contains the pixel center and is perpendicular to a top surface of said photoelectric conversion unit and located along the first direction and, and is asymmetric with respect to a plane which is perpendicular to the top surface of said photoelectric conversion unit and the first direction and contains the pixel center.

9. The solid-state imaging device according to claim 7,
wherein, in each of said pixels, a region in which said first lens is not formed and which is at an edge in a direction opposite to the first direction with respect to the pixel center is larger than a region in which said first lens is not formed and which is at an edge in the first direction with respect to the pixel center.

10. The solid-state imaging device according to claim 1,
wherein said pixels include a first pixel and a second pixel, and
the first direction of said first pixel and the first direction of said second pixel are different from each other.

11. The solid-state imaging device according to claim 10,
wherein said pixels are included in cells having a multi-pixel one-cell structure, and
each of said cells includes said first pixel and said second pixel.

12. The solid-state imaging device according to claim 1,
wherein, in each of said pixels, said photoelectric conversion unit is placed according to a first placement cell, and said first lens and said second lens is placed according to a second placement cell,
in a pixel array in which said pixels are arranged in rows and columns, a center of said second placement cell is displaced further toward a center of said pixel array with respect to the center of said first placement cell as said second placement cell is farther from the center of said pixel array and closer to a periphery of said pixel array,
the effective center of the light-receiving face of said photoelectric conversion unit is displaced from the center of said first placement cell in the first direction,
the center of said first lens is displaced from the center of said second placement cell in the first direction, and
said second lens has the focal position displaced from the center of said second placement cell in the first direction.

13. The solid-state imaging device according to claim 1,
wherein said first lens is made of an acrylic resin.

14. The solid-state imaging device according to claim 1,
wherein said second lens is made of silicon nitride or silicon oxynitride.

15. A method of manufacturing a solid-state imaging device including a plurality of pixels arranged in rows and columns,
each of the pixels including:
a photoelectric conversion unit which performs photoelectric conversion to convert light into an electric signal;
a first lens which collects incident light; and
a second lens which collects, onto the photoelectric conversion unit, the incident light collected by the first lens,
said method comprising:
forming the photoelectric conversion unit which has a light-receiving face having an effective center displaced from a pixel center in a first direction;
forming the second lens having a focal position displaced from the pixel center in the first direction; and
forming the first lens having a center displaced from the pixel center in the first direction.

16. The method of manufacturing a solid-state imaging device according to claim 15,
wherein said forming of the first lens includes:
pattering a material for the first lens; and
reflowing the patterned material so as to form the first lens having an asymmetric shape and a convex surface.

17. The method of manufacturing a solid-state imaging device according to claim 16,
wherein, in said patterning, the material for the first lens is patterned using a mask which is axisymmetric with respect to a centerline containing the pixel center and extending in the first direction and is asymmetric with respect to a centerline containing the pixel center and extending orthogonally to the first direction.

18. The method of manufacturing a solid-state imaging device according to claim 17,
wherein, in said patterning, the material for the first lens is patterned, using the mask, into a pentagon formed by cutting off one of corners of a rectangle, and
the corner cut off from the rectangle is located in a direction opposite to the first direction with respect to the pixel center.
